(19) United States
(12) Patent Application Publication
(10) Pub. No.: US 2002/0132471 A1
(43) Pub. Date: Sep. 19, 2002

(54) High modulus film structure for enhanced electromigration resistance

(75) Inventors: Brett H. Engel, Fishkill, NY (US); Vincent J. McGahay, Poughkeepsie, NY (US)

Correspondence Address: Connolly Bove Lodge & Hutz LLP, P.O. Box 19088, Washingotn, DC, 20036-3425, US

(73) Assignee: International Business Machines Corporation, Armonk, NY (US)

(21) Appl. No.: 09/810,312

(22) Filed: Mar. 16, 2001

(51) Int. Cl. H01L 21/4763; H01L 21/44

(52) U.S. Cl. 438/639; 438/687; 438/927

(57) ABSTRACT

The invention produces an integrated line/via interconnect structure comprising a high-modulus liner material that provides compression and back pressure, thus enhancing electromigration resistance and aiding heat dissipation.

### FIELD OF THE INVENTION

The invention relates to interconnect linings that provide for enhanced electromigration resistance. The invention also relates to a heat-dissipative interconnect liner.

### BACKGROUND OF THE INVENTION

Along with emerging low dielectric constant (low-k) technology is a growing concern for electromigration resistance. Low-k materials are required in the interconnect layers of high performance integrated circuits in order to reduce signal delay, signal distortion, and power consumption, all of which are related to the parasitic capacitance between neighboring wires. For a given configuration of wires, the capacitance can be reduced by reducing the dielectric constant of the insulators in which the wires are embedded.

Inherent in these low-k materials is a low Young Modulus of elasticity (E). In comparison to a copper/silicon oxide ILD (E=72 GPa) system, copper/low-k systems can experience early electromigration failure. It is believed that these mechanically weak low-k materials (E<5 GPa) do not provide substantial back pressure (to the copper interconnect), thus resulting in a considerable reduction of electromigration lifetime. Additionally, these low-k materials do not dissipate heat nearly as efficiently as a conventional oxide. The effect of this is a local heating also resulting in a reduction in electromigration lifetime. Consequently, there is a need for a high modulus liner material that will enhance electomigration resistance and lifetime by providing compression and back pressure while aiding in the dissipation of heat (without greatly increasing the effective dielectric constant).

Furthermore, there is currently no liner deposition technique that will result in a film deposition everywhere except the bottoms of the vias; all existing processes result in sidewall spacers only or in a full blanket coating. In order for a non-conductive, high modulus film to be fully effective, it must incorporate a bottom liner as well as a sidewall liner. The film, however, cannot block the conductive path between the via and the underlying metal. The present invention is a process that will deposit a liner material and effectively etch it away only in the bottoms of the vias.

### SUMMARY OF INVENTION

The invention provides an integrated line/via structure suitable for incorporation into integrated circuit devices, capable of being fabricated by, for example, single damascene and dual damascene methods. The structure comprising: a first dielectric layer comprised of low E material; at least one embedded copper line wherein the upper surface of the copper line is substantially coplanar with the upper surface of the first dielectric layer; a first metal level cap deposited over the upper surface of the first dielectric layer; a second dielectric layer comprised of low E material deposited on the first metal cap; at least one via interconnect (single damascene) or via/line interconnect (dual damascene), having walls of the single or dual damascene interconnect, formed in the second dielectric layer and formed above and abutting the at least one copper line. Crucially, the walls of the via are lined with a structural film and a conductive liner. However, the structural film is caused not to be present along the via bottom, thus facilitating good electrical communication with the underlying line.

The invention provides a method of fabricating such a structure.

An aspect of the invention is means for increasing the electromigration resistance of structures fabricated using low-k materials. A further aspect is the provision of means for increasing the heat dissipation of structures formed of low-k materials. The invention thus provides line-via structures having an increased mean-time-to-failure.

Still other objects and advantages of the present invention will become readily apparent by those skilled in the art from the following detailed description, wherein it is shown and described preferred embodiments of the invention, simply by way of illustration of the best mode contemplated of carrying out the invention. As will be realized the invention is capable of other and different embodiments, and its several details are capable of modifications in various obvious respects, without departing from the invention. Accordingly, the description is to be regarded as illustrative in nature and not as restrictive.

### BRIEF DESCRIPTION OF DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 illustrates a preferred embodiment of the invention as a dual damascene line/via structure having an embedded structural film; and

FIG. 2 illustrates a preferred embodiment of the invention as a single damascene line/via structure.

### DETAILED DESCRIPTION OF A PREFERRED EMBODIMENT

Reference is made to the figures to illustrate selected embodiments and preferred modes of carrying out the invention. It is to be understood that the invention is not hereby limited to those aspects depicted in the figures.

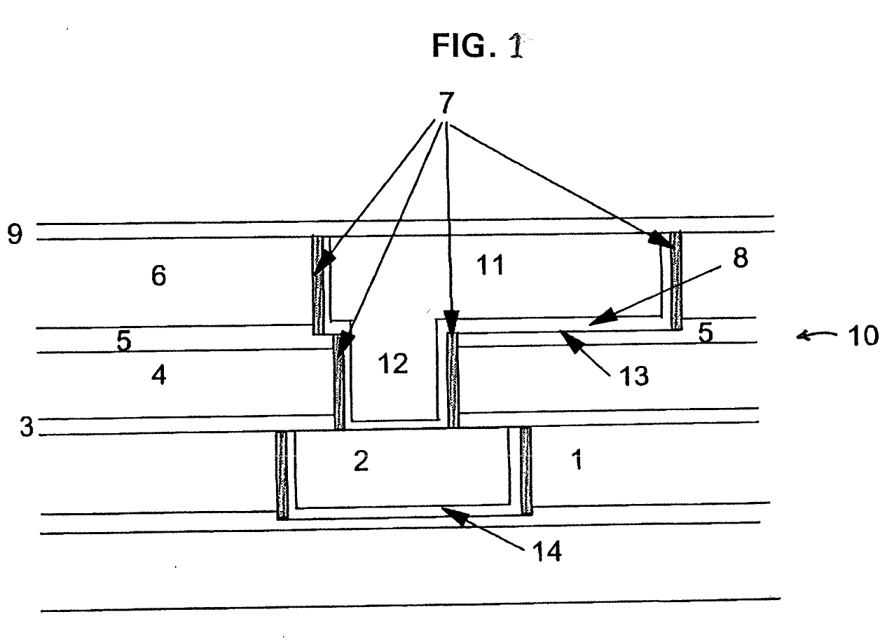

With reference to FIG. 1, disclosure is made of a preferred embodiment of the invention as a dual damascene line/via structure having an embedded structural film. The structure comprises three basic levels: basal 1, in which at least one line is embedded, intermediate 4, in which at least one via landing on the aforementioned line is embedded, and upper 6, in which at least one wire comprising a dual damascene line/via interconnect with the aformentioned via is embedded.

The preferred embodiment has at least one dual damascene line/via interconnect wherein the line and via walls and line bottom are lined with successive laminations of structural films and conductive liner.

In other embodiments, the via walls are laminated first with a conductive liner and then with a structural film. A further embodiment comprises a conductive liner, structural film, conductive liner tri-lamination. A further embodiment has only a lamination of structural film.

The basal level 1 comprises a layer of low E dielectric material. A preferred material is the low-k polymeric semiconductor dielectric resin, SiLK® (SiLK is a registered Trademark of Dow Chemical Company). Suitable materials include organics, such as BCB (Dow Chemical); porous organics, such as may be derived from SiLK and BCB; inorganic materials, such as Nanoglass; and hybrid organic/inorganic materials such as Coral (Novellus) and Black Diamond (Applied Materials). Formed within basal layer 1 is at least one, and more typically a plurality, of conduction lines 2. The conduction lines are typically copper, but other high-conductivity materials may be used. The basal layer is capped with a metal level cap 3, preferably silicon nitride, but silicon carbide is used in the alternative. The thickness of cap 3 is preferably 400 Å, and typically varies from about 100 Å to about 1000 Å. An opening is provided in the cap in the region above the conduction line(s) where it is desired to provide electrical contact with subsequently formed line/via interconnect 10. The thickness of this layer is preferably 3000 Å, and typically varies from about 1000 Å to about 10,000 Å.

Formed above cap 3 is an intermediate layer 4 comprised of low E dielectric material. This material is typically the same material chosen for the basal layer 1, but may be any suitable material. The thickness of this layer is preferably 3000 Å, but may vary from about 1000 Å to about 10,000 Å. Layered above intermediate layer 4 is a second structural film, also referred to as an embedded structural film 5. This film preferably comprises silicon nitride, but may also comprise silicon oxide, silicon carbide, or silicon oxycarbide. The thickness of this film is preferably 500 Å, and typically varies from about from about 200 Å to about 1100 Å. However, in any event, film 5 needs to be thicker than the cap 3 if any of ii is to remain at the bottoms of the lines 11 when the cap is opened during the via etch.

An upper layer 6 is provided over structural film 5. Layer 6 comprises similar low E dielectric materials as comprise layers 1 and 4. Typically the same material is chosen for all three layers. The thickness of this layer is preferably about 3000 Å, and typically varies from about 1000 Å to about 10,000 Å.

Dual damascene line/via interconnects 10, in registration with the conductive lines 2, are provided through the upper 6 and intermediate 4 dielectric layers and through the embedded film 5. The interconnects are defined in such manner that they have a line portion 11 and a via 12 in contact with the conducting lines 2. In areas where the interconnect has only lines and no vias, the line bottom 13 sits on or within the embedded structural film 5. The junction of the via and line portions forms a shelf 13 of embedded structural film.

The line and via walls are lined with film laminations. In the preferred embodiment, a first structural film 7 contacts the via walls. This structural film preferably comprises silicon nitride, but may also comprise silicon oxide, silicon carbide, or silicon oxycarbide. The thickness of this film is typically 100 Å, but may vary from about from about 50 Å to about 1000 Å. A conductive liner 8 is formed along the first structural film 7 as well as along via bottoms above and in contact with the conductive line 2.

Vias 10 are then filled with a conductive metal, typically copper, but any high conductivity material may be used. In the case of copper interconnects, excess copper and conducting liner deposited over the surface of the upper layer 6 is typically removed by chemical mechanical polishing. Finally, the line-via structure is finished by applying a blanket film of silicon nitride 8. The thickness of cap 8 is preferably 400 Å, but may vary from about 100 Å to about 1000 Å.

Further embodiments invoke a tri-laminate lining with structural film 7 sandwiched between two plies of conductive liner 8. Still other embodiments comprise only the structural film. In some embodiments of the invention, conduction line 2 is provided a conductive liner 14. Other embodiments lack this liner.

An aspect of the invention is a method of fabricating the dual damascene line/via structure.

The process includes creating the unfilled dual damascene structure by depositing a cap layer 3 such as silicon nitride followed by depositing a low-k film 4 such as SiLK. A structural film 5 such as silicon nitride is then deposited followed by a low-k film 6 such as SiLK. A hardmask such as a silicon nitride/silicon oxide bilayer is deposited. Line level lithography employing a photoresist, such as a negative or positive resist, is now carried out whereby each desired line image is selectively etched into the silicon oxide stopping on the silicon nitride of the hardmask. The via level lithography is performed by etching vias through the silicon nitride of the hardmask and structural low-k film 6 stopping on structural film 5. Any remaining photoresist is removed.

The exposed silicon nitride of the hardmask and structural film 5 are simultaneously opened by reactive ion etching (RIE). Line 11 is etched in low-k film 6 and etching of via 12 is continued into film 4. The exposed nitride cap 3 is opened at the via bottom by RIE. The dual damascene structure is cleaned, for example, by wet cleaning.

The structural films on the walls of the lines/vias are now created by depositing high modulus structural film 7 followed by anisotropically etching the structural film 7 from the bottom of the via 12 and line 11.

The interconnects are now filled with the conductor by depositing a conductor liner followed by electroplating copper. The excess copper, conducting liner, and hardmask are planarized by chemical-mechanical polishing (CMP).

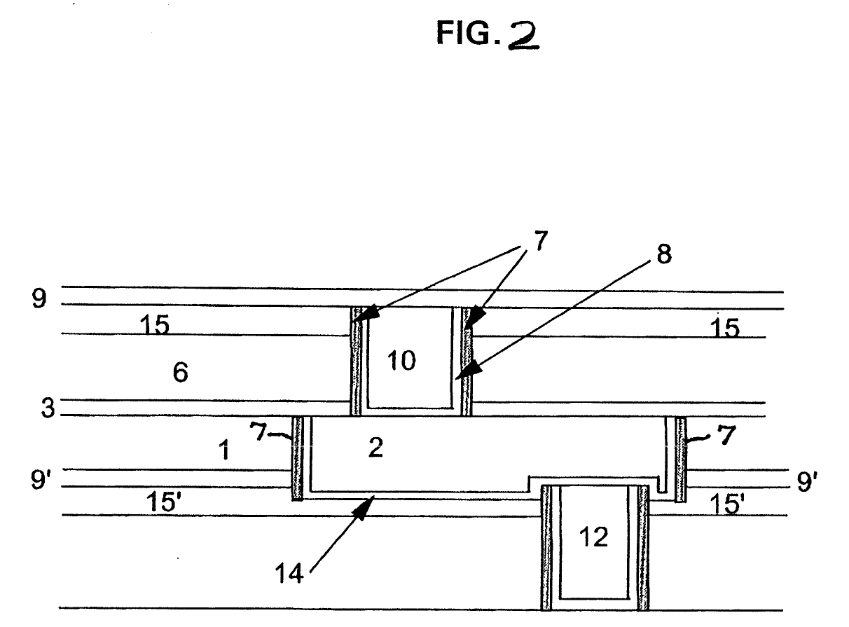

With reference to FIG. 2 disclosure is made of a preferred embodiment of the invention as a single damascene line/via structure. The structure comprises two basic levels: basal 1 and upper 6.

The basal level 1 comprises a layer of low E dielectric material. A preferred material is the low-k polymeric semiconductor dielectric resin, SiLK® (SiLK is a registered Trademark of Dow Chemical Company). Suitable other materials include organics, such as BCB (Dow Chemical); porous organics, such as may be derived from SiLK and BCB; inorganic materials, such as Nanoglass, and hybrid organic/inorganic materials such as Coral (Novellus) and Black Diamond (Applied Materials). Formed within basal layer 1 is at least one, and more typically a plurality, of conduction lines 2. The conduction lines are typically copper, but other high-conductivity materials may be used. The basal layer is capped with a metal level cap 3, preferably silicon nitride, but silicon carbide is used in the alternative. The thickness of cap 3 is preferably 400 Å, and typically varies from about 100 Å to about 1000 Å. An opening is provided in the cap in the region above the conduction line(s) where it is desired to provide electrical contact with subsequently formed single damascene via interconnect 10. The height of this via is preferably about 3000 Å and is typically about 1000 Å to about 10,000 Å.

Formed above cap 3 is an upper layer 6 comprised of low k dielectric material. This material is typically the same material chosen for the basal layer 1, but may be any suitable material. The thickness of this layer is preferably 3000 Å and typically varies from about 1000 Å to about 10,000 Å.

A hardmask layer such as silicon nitride is provided over layer 6. This hardmask layer 15 is to provide a structural film at the bottom of the single damascene lines built over the vias. The hardmask layer 15 is typically about 100 Å to about 1000 Å thick and preferably about 300 Å thick.

Single damascene line via interconnects 10, in registration with the conductive lines 2, are provided through the upper 6 dielectric layer. The via walls are lined with a structural film 7. This film preferably comprises material having as low dielectric constant as possible, preferably comprised of silicon carbide, but may also comprise silicon oxide. The thickness of this film is typically 100 Å, but may vary from about from about 50 Å to about 1000 Å. A conductive liner 8 is formed along the first structural film 7 as well as along via bottoms above and in contact with the conductive line 2. Vias 10 are then filled with a conductive metal, typically copper, but any high conductivity material may be used. Finally, the line-via structure is finished by applying a blanket film of silicon nitride 8. The thickness of cap 8 is preferably 400 Å, and typically varies from about 100 Å to about 1000 Å.

Other embodiments of the invention reverse the order of the laminations lining via 10. Some embodiments have the conductive liner 8 contact the via walls. Further embodiments invoke a tri-laminate lining with structural film 7 sandwiched between two plies of conductive liner 8. Still other embodiments comprise only the structural film. In general, conduction line 2 can have a structure similar to the line 12 including all the embodiments discussed.

An aspect of the invention is a method of fabricating the single damascene line/via structure.

The unfilled single damascene via structure is created by depositing a cap 3 such as nitride followed by depositing a low-k film 6 such as SiLK. A hardmask layer such as silicon nitride is deposited. Via level lithography is carried out employing a photoresist whereby a via is etched through hardmask and low-k film 6 stopping on cap 3. Remaining photoresist is then removed. Exposed nitride cap 3 is opened at the via bottom such as by employing RIE.

The structure is then cleaned such as by wet cleaning.

Structural films are created on the walls of the vias by depositing a high modulus structural film 7 and anisotropically etching the structural film 7 from the bottom of the via 10.

The interconnects are now filled with conductor by depositing a conductor liner followed by electroplating copper. The excess copper conducting linger and hardmask are planarized by chemical-mechanical polishing (CMP).

A single damascene line is formed in the same way as the via, but, in the case of the line, it is not necessary to leave the hardmask intact. For example, the unfilled damascene line structure is created by depositing a cap 9′ such as nitride followed by depositing a low-k film 1 such as SiLK. A hardmask layer such as silicon nitride is deposited. Line level lithography is carried out employing a photoresist whereby a line is etched through hardmask and low-k film 1 stopping on cap 9′. Remaining photoresist is then removed. Exposed nitride cap 9′ is opened at the line bottom such as by employing RIE. Any exposed hardmask is not removed.

The structure is then cleaned such as by wet cleaning.

Structural films are created on the walls of the lines by depositing a high modulus structural film 7 and anisotropically etching the structural film 7 from the bottom of the line.

The interconnects are now filled with the conductor by depositing a conductor liner followed by electroplating copper. The excess copper conducting liner and hardmask are planarized by chemical-mechanical polishing (CMP).

Alternative structures can also be achieved according to the present invention by modifying the sequence of process steps. For example, the cap open step after the via etch is skipped and the cap is opened after the structural film is deposited.

It will, therefore, be appreciated by those skilled in the art having the benefit of this disclosure that this invention is capable of producing an integrated line/via structure comprising a high-modulus liner material that provides compression and back pressure, thus enhancing electromigration resistance and aiding heat dissipation. Furthermore, it is to be understood that the form of the invention shown and described is to be taken as presently preferred embodiments. Various modifications and changes may be made to each and every processing step as would be obvious to a person skilled in the art having the benefit of this disclosure. It is intended that the following claims be interpreted to embrace all such modifications and changes and, accordingly, the specification and drawings are to be regarded in an illustrative rather than a restrictive sense. Moreover, it is intended that the appended claims be construed to include alternative embodiments.

What is claimed is:

1. A method of fabricating a dual damascene integrated line/via structure which comprises:
a) depositing a cap layer on a substrate;
b) depositing a first low-k film on said cap layer;
c) depositing a structural film layer over said low-k film;
d) depositing a second low-k film on said structural film layer;
e) depositing a hardmask bilayer comprising a first layer of a first material and a second upper layer of a second and different material over said second low-k film;
f) selectively etching a line into the upper layer of the hardmask and stopping on the first layer of the hardmask;
g) etching a via through the hardmask and said second low-k film stopping on said structural film;
h) opening exposed hardmask and said structural film;
i) etching said line into said second low-k film and continue etching of said via into said first low-k film;
j) opening exposed cap layer at the bottom of said via;
k) depositing a high modulus structural film and anisotropically etching said high modulus structural film from the bottom of said via and said line; and
l) depositing a conducting liner layer and electroplating copper in said via and said line.

2. The method of claim 1, wherein said cap layer comprises silicon nitride or silicon carbide.

3. The method of claim 1, wherein said cap layer is about 100 Å to about 1000 Å thick.

4. The method of claim 1, wherein said hardmask comprises a silicon nitride/silicon oxide bilayer.

5. The method of claim 1, wherein said exposed hardmask and structural film are opened by reactive ion etching.

6. The method of claim 1, wherein said structural film is thicker than said cap liner.

7. The method of claim 1, wherein said structural film comprises silicon nitride.

8. The method of claim 1, wherein said etching employs a positive or negative photoresist.

9. A method of fabricating a single damascene via structure which comprises:
a) depositing a cap layer on a substrate;
b) depositing a low-k film on said cap layer;
c) depositing a hardmask on said low-k film;
d) etching a via through said hardmask and low-k film stopping on said cap layer;
e) opening exposed cap layer at the bottom of said via;
f) depositing a high modulus structural film;
g) anisotropically etching said structural film from the bottom of said via; and
h) depositing a conducting liner layer and electroplating copper in said via.

10. The method of claim 9, wherein said cap layer comprises silicon nitride or silicon carbide.

11. The method of claim 9, wherein said cap layer is about 100 Å to about 1000 Å thick.

12. The method of claim 9, wherein said hardmask comprises a silicon nitride/silicon oxide bilayer.

13. The method of claim 9, wherein said exposed hardmask and structural film are opened by reactive ion etching.

14. The method of claim 9, wherein said structural film comprises silicon nitride.

15. The method of claim 8, wherein said etching employs a positive or negative photoresist.

16. A method of fabricating a single damascene line structure which comprises:
a) depositing a cap layer on a substrate;
b) depositing a low-k film on said cap layer;
c) depositing a hardmask on said low-k film;
d) etching a line through said hardmask and low-k film stopping on said cap layer;
e) opening exposed cap layer at the bottom of said line;
f) depositing a high modulus structural film;
g) anisotropically etching said structural film from the bottom of said line; and
h) depositing a conducting liner layer and electroplating copper in said line.

17. The method of claim 16, wherein said cap layer comprises silicon nitride or silicon carbide.

18. The method of claim 16, wherein said cap layer is about 100 Å to about 1000 Å thick.

19. The method of claim 16, wherein said hardmask comprises a silicon nitride/silicon oxide bilayer.

20. The method of claim 16, wherein said exposed hardmask and structural film are opened by reactive ion etching.

21. The method of claim 16, wherein said structural film comprises silicon nitride.

22. The method of claim 16, wherein said etching employs a positive or negative photoresist.
